(19) United States
(12) Patent Application Publication
(10) Pub. No.: US 2026/0218989 A1
(43) Pub. Date: Jul. 30, 2026

(54) THREE-DIMENSIONAL LOOP TYPE VAPOR CHAMBER AND HEAT DISSIPATION DEVICE WITH THE SAME

(71) Applicant: DELTA ELECTRONICS, INC., Taoyuan City (TW)

(72) Inventor: Chao-Wen LU, Taoyuan City (TW)

(21) Appl. No.: 19/382,276

(22) Filed: Nov. 7, 2025

Related U.S. Application Data
(60) Provisional application No. 63/748,993, filed on Jan. 24, 2025.

(30) Foreign Application Priority Data
May 16, 2025 (CN) 202510632882.1

(51) Int. Cl. F28D 15/04

(52) U.S. Cl. CPC F28D 15/043

(57) ABSTRACT

A three-dimensional loop type vapor chamber includes a plate vapor chamber and a plurality of U-shaped heat pipes. The plate vapor chamber includes an upper casing, a lower casing, and a capillary structure. The capillary structure is disposed between the upper casing and the lower casing. A heat absorption area and a heat dissipation area are formed within the plate vapor chamber. The capillary structure includes a capillary structure cavity located in the heat absorption area. The upper casing in the heat absorption area comprises a plurality of first openings, and the upper casing in the heat dissipation area comprises a plurality of second openings. Each U-shaped heat pipe includes an inlet end and an outlet end respectively fixed to a corresponding first opening and a second opening of the upper casing of the plate vapor chamber.

### RELATED APPLICATIONS

This application claims priority to U.S. Provisional Application Serial Number 63/748,993 filed January 24, 2025, and China Application Serial Number 202510632882.1 filed May 16, 2025, the disclosures of which are incorporated herein by reference in their entireties.

### BACKGROUND

### TECHNICAL FIELD

The present disclosure relates to a three-dimensional loop type vapor chamber. More particularly, the present disclosure relates to a heat dissipation device having a three-dimensional loop type vapor chamber.

### DESCRIPTION OF RELATED ART

With the advancement of technology, electronic products have become increasingly popular and have gradually changed the lifestyle or working patterns of many people. As computer processing capabilities continue to increase, temperature control for electronic components such as central processing units (CPUs) and graphics processing units (GPUs) has become more and more important.

Electronic components such as CPUs and GPUs generate heat during operation, requiring proper cooling to achieve optimal performance. To ensure that electronic components such as CPUs can operate at ideal temperatures, the configuration of a suitable heat dissipation device significantly affects the performance of electronic devices.

Therefore, there is a need to effectively improve the heat dissipation efficiency of heat dissipation devices to reduce the operating temperature of electronic components so as to enhance the overall operating efficiency of electronic devices.

### SUMMARY

The summary of the present invention is intended to provide a simplified description of the disclosure to enable readers to have a basic understanding of the disclosure. The summary of the present invention is not a complete overview of the disclosure, and it is not intended to point out the importance of the embodiments / key elements of the present invention or define the scope of the invention.

One objective of the present invention is to provide a three-dimensional loop type vapor chamber and a heat dissipation device having a three-dimensional loop type vapor chamber able to effectively improve heat dissipation efficiency and further enhance the overall operating efficiency of the electronic devices.

To achieve these and other advantages and in accordance with the objective of the embodiments of the present invention, as the embodiment broadly describes herein, the embodiments of the present invention provides a three-dimensional loop type vapor chamber including a plate vapor chamber and a plurality of U-shaped heat pipes. The plate vapor chamber includes an upper casing, a lower casing, and a capillary structure. The capillary structure is disposed between the upper casing and the lower casing. A heat absorption area and a heat dissipation area are formed within the plate vapor chamber. The capillary structure includes a capillary structure cavity located in the heat absorption area. The upper casing in the heat absorption area comprises a plurality of first openings, and the upper casing in the heat dissipation area comprises a plurality of second openings. Furthermore, each U-shaped heat pipe comprises an inlet end and an outlet end respectively fixed to a corresponding first opening and a corresponding second opening of the upper casing of the plate vapor chamber. The inlet ends of the U-shaped heat pipes are connected to the first openings and communicate with the capillary structure cavity.

In some embodiments, the capillary structure includes a first capillary structure region and a second capillary structure region. The first capillary structure region surrounds the second capillary structure region, and the first capillary structure region covers the outlet ends of the U-shaped heat pipes.

In some embodiments, each of the U-shaped heat pipes includes a tube wall and a plurality of capillary structures formed within the tube wall.

In some embodiments, each of the U-shaped heat pipes includes a first upright section, a second upright section, and a connecting section. The first upright section is connected to the corresponding first opening on the upper casing. The second upright section is connected to the corresponding second opening on the upper casing. The connecting section is connected between the first upright section and the second upright section, and the connecting section radially extends outward from the center of the plate vapor chamber.

According to another embodiment of the present invention, a heat dissipation device is provided, including a three-dimensional loop type vapor chamber and a plurality of heat dissipation fins. The three-dimensional loop type vapor chamber includes a plate vapor chamber and a plurality of U-shaped heat pipes. The plate vapor chamber includes an upper casing, a lower casing, and a capillary structure disposed between the upper casing and the lower casing. The plate vapor chamber forms a heat absorption area and a heat dissipation area, and the capillary structure includes a capillary structure cavity located in the heat absorption area. Additionally, the U-shaped heat pipes are fixed to the first openings located in the heat absorption area and the second openings located in the heat dissipation area of the upper casing of the plate vapor chamber. Each U-shaped heat pipe includes an inlet end and an outlet end. The inlet end of the U-shaped heat pipe is connected to the first opening and communicates with the capillary structure cavity. Furthermore, the heat dissipation fins are formed with a plurality of heat dissipation fin openings, and the U-shaped heat pipes are disposed within the heat dissipation fin openings.

In some embodiments, each of the U-shaped heat pipes includes a first upright section, a second upright section, and a connecting section. The first upright section is connected to a corresponding first opening on the upper casing. The second upright section is connected to a corresponding second opening on the upper casing. The connecting section is connected between the first upright section and the second upright section, and the connecting section radially extends outward from the center of the plate vapor chamber.

In some embodiments, a gap is included between the first upright section and the heat dissipation fin opening end face of the corresponding heat dissipation fin opening.

In some embodiments, the second upright section is directly connected to the heat dissipation fin opening end face of the corresponding heat dissipation fin opening.

In some embodiments, the heat dissipation device further includes a housing formed with an air inlet and an air outlet to guide a heat dissipation airflow.

In some embodiments, the housing includes an upper cover, a first side wall, and a second side wall. The first side wall is connected to one side of the upper cover, and the second side wall is connected to the other side of the upper cover. The heat dissipation fins are disposed between the upper cover, the first side wall, the second side wall, and the plate vapor chamber.

Hence, the three-dimensional loop type vapor chamber of the present invention may utilize a plate vapor chamber combined with U-shaped heat pipes. By using the capillary structure of the plate vapor chamber to cover the outlet ends of the U-shaped heat pipes located in the heat dissipation area, heat dissipation vapor may only enter the U-shaped heat pipes through the inlet ends located in the heat absorption area. The heat dissipation fluid flows unidirectionally within the U-shaped heat pipes, effectively preventing the heat dissipation liquid from hindering the flow efficiency of the heat pipes. Furthermore, the portion of the U-shaped heat pipe located in the heat absorption area preferably avoids direct contact with the heat dissipation fins to further prevent premature condensation of the heat dissipation vapor, while the portion of the U-shaped heat pipe located in the heat dissipation area preferably directly contacts the heat dissipation fins to enhance heat dissipation efficiency.

### BRIEF DESCRIPTION OF THE DRAWINGS

The disclosure may be more fully understood by reading the following detailed description of the embodiment, with reference made to the accompanying drawings as follows:

FIG. 1 is a schematic perspective view of a heat dissipation device with a three-dimensional loop type vapor chamber according to an embodiment of the present invention;

FIG. 2 is a schematic perspective view of a three-dimensional loop type vapor chamber according to another embodiment of the present invention;

FIG. 3 is a schematic cross-sectional view of the heat dissipation device with a three-dimensional loop type vapor chamber of FIG. 1;

FIG. 4 is a partially enlarged schematic view of the heat dissipation device with a three-dimensional loop type vapor chamber of FIG. 3; and

FIG. 5 is a schematic cross-sectional perspective view of the heat pipe of the three-dimensional loop type vapor chamber.

### DETAILED DESCRIPTION

The following is a detailed description of the embodiments in conjunction with the accompanying drawings, but the provided embodiments are not intended to limit the scope of the disclosure, and the description of the structure and operation is not utilized to limit the execution sequence thereof. The structure of the recombination of components and the resulting devices with equal functions are all within the scope of this disclosure. In addition, the drawings are for illustration purposes only, and are not drawn according to the original scale. For ease of understanding, the same reference numbers are utilized in the drawings and the description to refer to the same or like parts.

In addition, the terms utilized in the entire description and the scope of the patent application, unless otherwise specified, usually have the usual meaning of each term utilized in this field, in the content disclosed here and in the special content. Some terms utilized to describe the disclosure are discussed below or elsewhere in this specification to provide additional guidance to those skilled in the art in the disclosure.

In the implementation mode and the scope of the present application, unless the article is specifically limited in the context, "a" and "the" may generally refer to a single or pluralities. In the steps, the numbering is only utilized to conveniently describe the steps, rather than to limit the sequence and implementation.

Secondly, the words "comprising", "including", "having", "containing" and the like utilized in the present application are all open language, meaning including but not limited thereto.

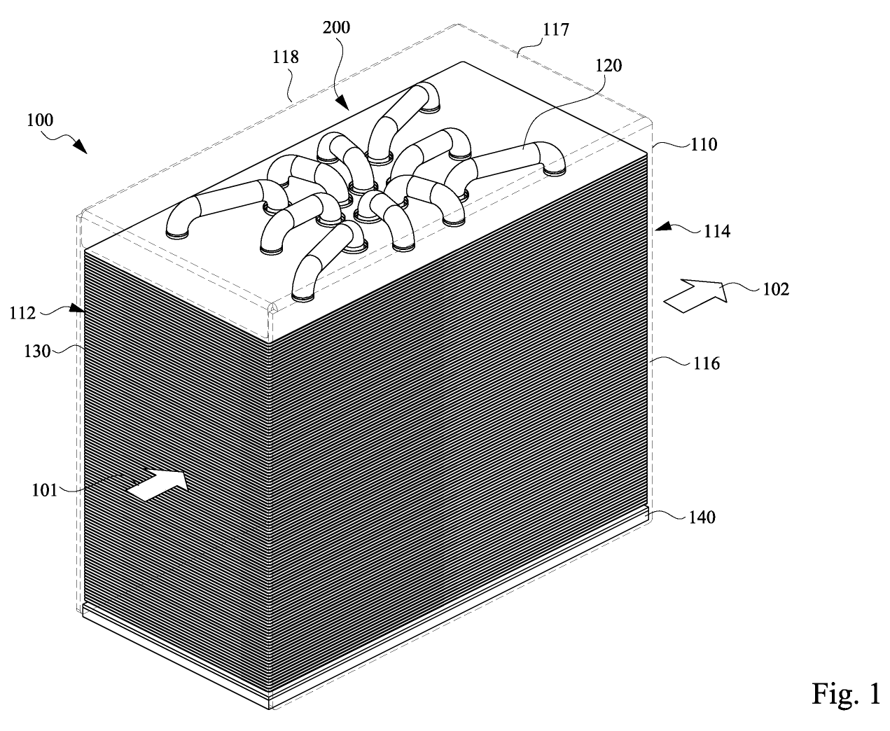

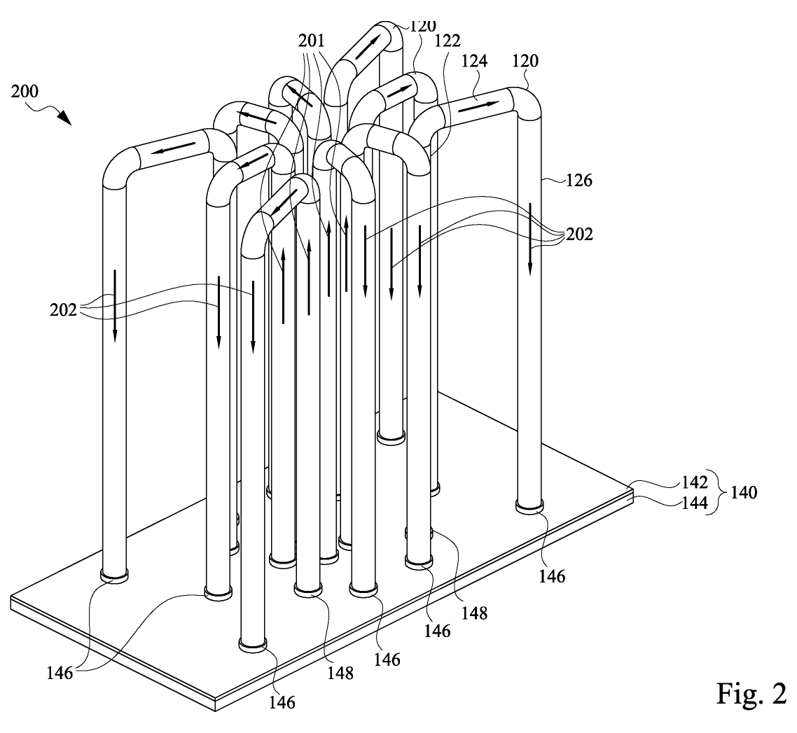

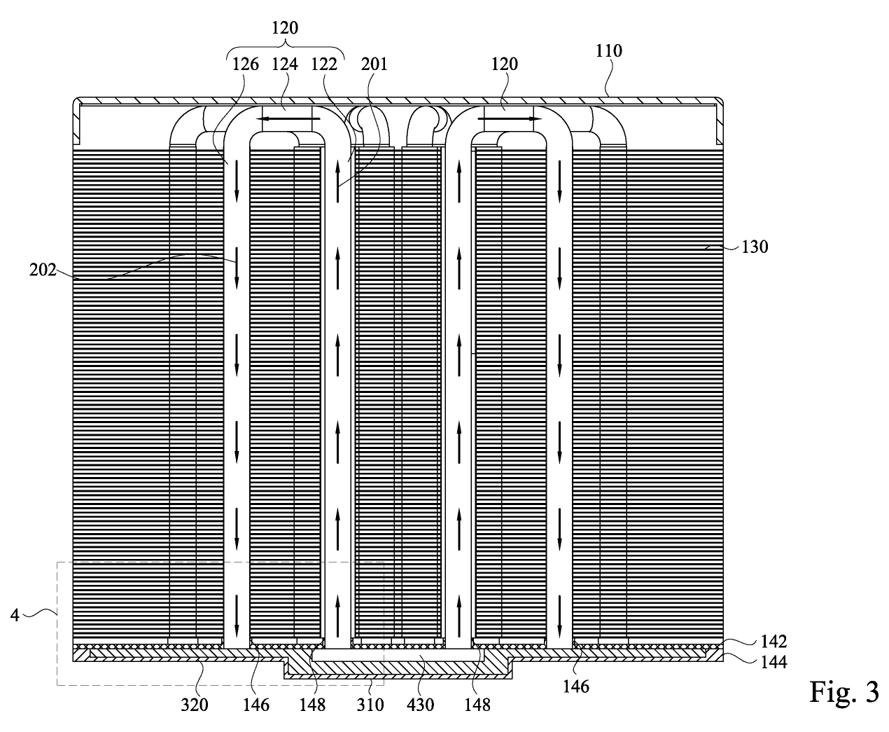

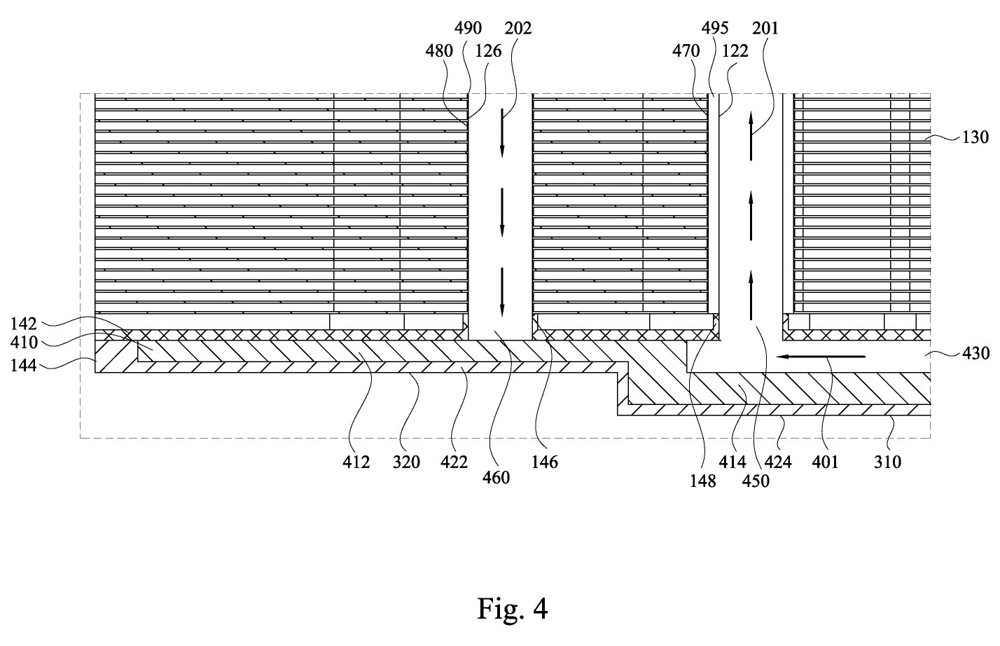

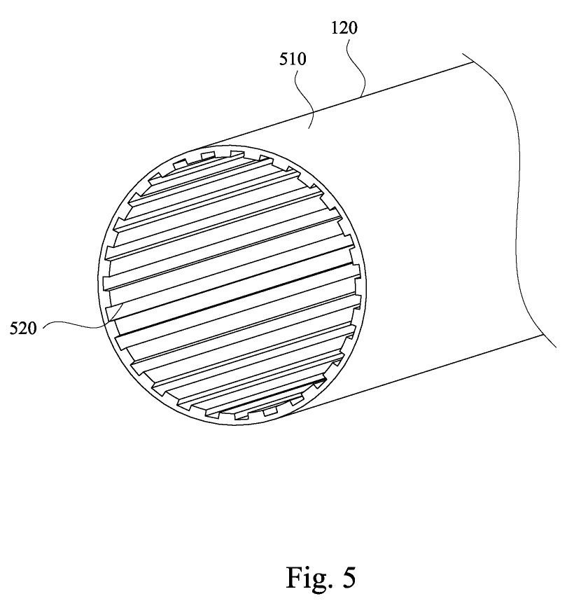

FIG. 1 is a schematic perspective view of a heat dissipation device having a three-dimensional loop type vapor chamber according to an embodiment of the present invention. FIG. 3 is a schematic cross-sectional view of the heat dissipation device having a three-dimensional loop type vapor chamber, and FIG. 4 is a partially enlarged schematic view of the heat dissipation device having a three-dimensional loop type vapor chamber. In addition, FIG. 2 is a schematic perspective view of a three-dimensional loop type vapor chamber according to another embodiment of the present invention. FIG. 5 is a schematic cross-sectional perspective view of the heat pipe of the three-dimensional loop type vapor chamber.

First, referring to FIGS. 1 and 2, as shown in the figures, the three-dimensional loop type vapor chamber 200 includes a plate vapor chamber 140 and a plurality of U-shaped heat pipes 120.

Referring to FIGS. 3 and 4 simultaneously, the plate vapor chamber 140 includes an upper casing 142, a lower casing 144, and a capillary structure 410. The capillary structure 410 is disposed between the upper casing 142 and the lower casing 144. In addition, the plate vapor chamber 140 forms a heat absorption area 310 and a heat dissipation area 320. For example, the heat absorption area 310 is located at the central position of the plate vapor chamber 140, and the heat dissipation area 320 surrounds the heat absorption area 310, but the present invention is not limited thereto.

In some embodiments, the height of the heat absorption area 310 is lower than that of the heat dissipation area 320 to facilitate contact with the heat source.

In some embodiments, the lower casing 144 includes a heat dissipation area lower casing 422 and a heat absorption area lower casing 424. The height of the heat absorption area lower casing 424 is lower than the height of the heat dissipation area lower casing 422 to form a recessed space for accommodating the capillary structure 410.

In some embodiments, the capillary structure 410 includes a first capillary structure region 412 and a second capillary structure region 414. For example, the first capillary structure region 412 surrounds the second capillary structure region 414. In some embodiments, the second capillary structure region 414 is located in the recessed position of the heat absorption area lower casing 424 to form a capillary structure cavity 430 located in the heat absorption area 310, but the present invention is not limited thereto. The capillary structure cavity 430 can also be directly formed by the recess of the second capillary structure region 414. In other words, the height of the heat absorption area lower casing 424 may not need to be lower than the height of the heat dissipation area lower casing 422, which does not depart from the spirit and scope of protection of the present invention.

Furthermore, the upper casing 142 includes a plurality of first openings 148 and a plurality of second openings 146. The first openings 148 are located in the heat absorption area 310, and the second openings 146 are located in the heat dissipation area 320.

In some embodiments, two ends of the U-shaped heat pipes 120 are respectively fixed to the first openings 148 and the second openings 146 of the upper casing 142 of the plate vapor chamber 140. In addition, each U-shaped heat pipe 120 includes an inlet end 450 and an outlet end 460. The inlet end 450 of the U-shaped heat pipe 120 is connected to the first opening 148, and the inlet end 450 of the U-shaped heat pipe 120 communicates with the capillary structure cavity 430.

Moreover, it is worth noting that the first capillary structure region 412 of the capillary structure 410 covers the outlet end 460 of the U-shaped heat pipe 120. Therefore, the heat dissipation liquid absorbs heat generated by the heat source in the heat absorption area 310 to form the heat dissipation vapor that flows along the vapor flow direction 401 to the inlet end 450 of the U-shaped heat pipe 120, and then moves upward along the vapor flow direction 201. At this time, since the outlet end 460 of the U-shaped heat pipe 120 and the second opening 146 of the upper casing 142 are covered by the capillary structure 410, the heat dissipation vapor may therefore not enter into the U-shaped heat pipe 120 through the outlet end 460 of the U-shaped heat pipe 120 and the second opening 146 of the upper casing 142 so as to effectively guide the moving direction of the heat dissipation fluid.

Referring to FIG. 3, as shown in the figure, in some embodiments, the U-shaped heat pipe 120 includes a first upright section 122, a connecting section 124, and a second upright section 126. The first upright section 122 is connected to a corresponding first opening 148 on the upper casing 142, and the second upright section 126 is connected to a corresponding second opening 146 on the upper casing 142. In addition, the connecting section 124 is connected between the first upright section 122 and the second upright section 126, and the connecting section 124 radially extends outward from a central position of the plate vapor chamber 140.

Therefore, the heat dissipation liquid absorbs heat generated by the heat source in the heat absorption area 310 to form a heat dissipation vapor so as to flow to the inlet end 450 of the U-shaped heat pipe 120 and then move upward along the vapor flow direction 201. The heat dissipation vapor then continuously moves upward along the first upright section 122 and enters into the connecting section 124 to radially move outward. Then, the heat dissipation fluid will move along the heat dissipation fluid moving direction 202 within the second upright section 126 to further reduce the temperature of the heat dissipation fluid. Subsequently, the cooled heat dissipation liquid will further move downward along the plurality of capillary structures 520 inside the tube wall 510 of the U-shaped heat pipe 120 to be transported to the first capillary structure region 412 of the capillary structure 410. Then, the heat dissipation liquid uses capillary action to be transported from the heat dissipation area 320 to the second capillary structure region 414 of the heat absorption area 310, and then performs heat dissipation of the heat source again.

Therefore, the heat dissipation fluid flows unidirectionally in the U-shaped heat pipe 120 without being hindered by the condensed heat dissipation liquid, which would impede the flow of heat dissipation vapor.

Referring again to FIGS. 1 and 3, as shown in the figures, a heat dissipation device 100 having a three-dimensional loop type vapor chamber 200 includes the aforementioned three-dimensional loop type vapor chamber 200 and a plurality of heat dissipation fins 130, which are formed with a plurality of heat dissipation fin openings. Referring to the heat dissipation fin opening end face 470 and the heat dissipation fin opening end face 480 in FIG. 4, the U-shaped heat pipes 120 are disposed within the heat dissipation fin opening end face 470 and the heat dissipation fin opening end face 480 of the heat dissipation fin openings.

Referring again to FIG. 4, as shown in the figure, a gap 495 is formed between the first upright section 122 and corresponding heat dissipation fin opening end faces 470. In other words, the first upright section 122 does not directly contact the heat dissipation fins 130 to avoid the heat dissipation vapor cooling too quickly, which would lead to condensation into heat dissipation liquid before reaching the connecting section 124, thereby hindering the flow of the heat dissipation fluid.

Furthermore, it is worth noting that, referring to the junction 490, the second upright section 126 of the U-shaped heat pipe 120 is directly connected to the corresponding heat dissipation fin opening end face 480 to effectively reduce the temperature of the heat dissipation fluid in the second upright section 126 of the U-shaped heat pipe 120, so that the heat dissipation fluid in the second upright section 126 effectively condenses into heat dissipation liquid. Then, through the capillary structures 520 in the tube wall 510 of the U-shaped heat pipe 120 and the capillary structure 410, the heat dissipation liquid is transported from the heat dissipation area 320 to the heat absorption area 310, and then performs heat dissipation of the heat source again, effectively improving the heat dissipation efficiency of the heat dissipation device 100.

Referring again to FIG. 1, according to another aspect of the present invention, a heat dissipation device 100 is provided. The heat dissipation device 100 further includes a housing 110. The housing 110 includes an upper cover 117, a first side wall 116, and a second side wall 118. The first side wall 116 and the second side wall 118 are respectively connected to two sides of the upper cover 117. In addition, the upper cover 117, the first side wall 116, and the second side wall 118 form an air inlet 112 and an air outlet 114 to effectively guide cool air 101 from the air inlet 112 to flow through the heat dissipation fins 130. The heat generated by the heat source is transferred to the heat dissipation fins 130 via the U-shaped heat pipes 120, and then transferred to the cool air 101. The heated air 102 is then exhausted from the air outlet 114 to dissipate heat from the heat source.

Furthermore, the heat dissipation fins 130 are disposed between the upper cover 117, the first side wall 116, the second side wall 118, and the plate vapor chamber 140 to enhance the heat dissipation efficiency of the heat dissipation device 100.

Accordingly, the three-dimensional loop type vapor chamber disclosed in the present invention can utilize a plate vapor chamber combined with U-shaped heat pipes. By using the capillary structure of the plate vapor chamber to cover the outlet ends of the U-shaped heat pipes located in the heat dissipation area, heat dissipation vapor can only enter the U-shaped heat pipes through the inlet ends located in the heat absorption area, and the heat dissipation fluid flows unidirectionally within the U-shaped heat pipes, effectively preventing the heat dissipation liquid from hindering the flow efficiency of the heat pipes. In addition, the portion of the U-shaped heat pipe located in the heat absorption area preferably avoids direct contact with the heat dissipation fins to further prevent premature condensation of the heat dissipation vapor, while the portion of the U-shaped heat pipe located in the heat dissipation area preferably directly contacts the heat dissipation fins to enhance heat dissipation efficiency.

Although the present disclosure has been disclosed above in terms of implementation, it is not intended to limit the present disclosure. Any person with ordinary knowledge in the field may make various variations and modifications without departing from the spirit and scope of the disclosure. Therefore, the spirit and scope of the appended claims should not be limited to the description of the embodiments contained herein.

What is claimed is:

1. A three-dimensional loop type vapor chamber, comprising:
a plate vapor chamber, comprising an upper casing, a lower casing, and a capillary structure, wherein the capillary structure is disposed between the upper casing and the lower casing, and a heat absorption area and a heat dissipation area are formed within the plate vapor chamber, and the capillary structure comprises a capillary structure cavity located in the heat absorption area; the upper casing in the heat absorption area comprises a plurality of first openings, and the upper casing in the heat dissipation area comprises a plurality of second openings; and
a plurality of U-shaped heat pipes, wherein each of the U-shaped heat pipes comprises an inlet end and an outlet end respectively fixed to a corresponding first opening and a corresponding second opening of the upper casing of the plate vapor chamber, wherein the inlet ends of the U-shaped heat pipes are connected to the first openings and communicate with the capillary structure cavity.

2. The three-dimensional loop type vapor chamber of claim 1, wherein the capillary structure comprises:
a first capillary structure region; and
a second capillary structure region, wherein the first capillary structure region surrounds the second capillary structure region, and the first capillary structure region covers the outlet ends of the U-shaped heat pipes.

3. The three-dimensional loop type vapor chamber of claim 1, wherein each of the U-shaped heat pipes comprises:
a tube wall; and
a plurality of capillary structures formed within the tube wall.

4. The three-dimensional loop type vapor chamber of claim 1, wherein each of the U-shaped heat pipes comprises:
a first upright section connected to the corresponding first opening on the upper casing;
a second upright section connected to the corresponding second opening on the upper casing; and
a connecting section connected between the first upright section and the second upright section, wherein the connecting section radially extends outward from a center of the plate vapor chamber.

5. A heat dissipation device, comprising:
a three-dimensional loop type vapor chamber, comprising:
a plate vapor chamber, comprising an upper casing, a lower casing, and a capillary structure, wherein the capillary structure is disposed between the upper casing and the lower casing, and a heat absorption area and a heat dissipation area are formed within the plate vapor chamber, and the capillary structure comprises a capillary structure cavity located in the heat absorption area; the upper casing in the heat absorption area comprises a plurality of first openings, and the upper casing in the heat dissipation area comprises a plurality of second openings; and
a plurality of U-shaped heat pipes, wherein each of the U-shaped heat pipes comprises an inlet end and an outlet end respectively fixed to a corresponding first opening and a corresponding second opening of the upper casing of the plate vapor chamber, wherein the inlet ends of the U-shaped heat pipes are connected to the first openings and communicate with the capillary structure cavity; and
a plurality of heat dissipation fins formed with a plurality of heat dissipation fin openings, wherein the U-shaped heat pipes are disposed within the heat dissipation fin openings.

6. The heat dissipation device of claim 5, wherein each of the U-shaped heat pipes comprises:
a first upright section connected to the corresponding first opening on the upper casing;
a second upright section connected to the corresponding second opening on the upper casing; and
a connecting section connected between the first upright section and the second upright section, wherein the connecting section radially extends outward from a center of the plate vapor chamber.

7. The heat dissipation device of claim 6, wherein a gap is formed between the first upright section and heat dissipation fin opening end faces of corresponding heat dissipation fin openings of the heat dissipation fin openings.

8. The heat dissipation device of claim 7, wherein the second upright section is directly connected to heat dissipation fin opening end faces of corresponding heat dissipation fin openings of the heat dissipation fin openings.

9. The heat dissipation device of claim 5, further comprising:
a housing formed with an air inlet and an air outlet to guide a heat dissipation airflow.

10. The heat dissipation device of claim 9, wherein the housing comprises:
an upper cover;
a first side wall connected to one side of the upper cover; and
a second side wall connected to another side of the upper cover, wherein the heat dissipation fins are disposed between the upper cover, the first side wall, the second side wall, and the plate vapor chamber.

11. A heat dissipation device, comprising:
a three-dimensional loop type vapor chamber, comprising:
a plate vapor chamber, comprising an upper casing, a lower casing, and a capillary structure, wherein the capillary structure is disposed between the upper casing and the lower casing, and a heat absorption area and a heat dissipation area are formed within the plate vapor chamber, and the capillary structure comprises a capillary structure cavity located in the heat absorption area; the upper casing in the heat absorption area comprises a plurality of first openings, and the upper casing in the heat dissipation area comprises a plurality of second openings; and
a plurality of U-shaped heat pipes, wherein each of the U-shaped heat pipes comprises an inlet end and an outlet end respectively fixed to a corresponding first opening and a corresponding second opening of the upper casing of the plate vapor chamber, wherein the inlet ends of the U-shaped heat pipes are connected to the first openings and communicate with the capillary structure cavity;
a plurality of heat dissipation fins formed with a plurality of heat dissipation fin openings, wherein the U-shaped heat pipes are disposed within the heat dissipation fin openings; and
a housing formed with an air inlet and an air outlet to guide a heat dissipation airflow, wherein the heat dissipation fins are disposed in the housing.

12. The heat dissipation device of claim 11, wherein each of the U-shaped heat pipes comprises:
a first upright section connected to the corresponding first opening on the upper casing;
a second upright section connected to the corresponding second opening on the upper casing; and
a connecting section connected between the first upright section and the second upright section, wherein the connecting section radially extends outward from a center of the plate vapor chamber.

13. The heat dissipation device of claim 12, wherein a gap is formed between the first upright section and heat dissipation fin opening end faces of corresponding heat dissipation fin openings of the heat dissipation fin openings.

14. The heat dissipation device of claim 13, wherein the second upright section is directly connected to heat dissipation fin opening end faces of corresponding heat dissipation fin openings of the heat dissipation fin openings.

15. The heat dissipation device of claim 11, wherein the housing comprises:
an upper cover;
a first side wall connected to one side of the upper cover; and
a second side wall connected to another side of the upper cover, wherein the heat dissipation fins are disposed between the upper cover, the first side wall, the second side wall, and the plate vapor chamber.
